(19) United States
(12) Patent Application Publication
(10) Pub. No.: US 2013/0277729 A1
(43) Pub. Date: Oct. 24, 2013

(54) FLOATING GATE TRANSISTOR MEMORY WITH AN ORGANIC SEMICONDUCTOR INTERLAYER

(71) Applicants: Tse Nga Ng, Palo Alto, CA (US); Janos Veres, San Jose, CA (US)

(72) Inventors: Tse Nga Ng, Palo Alto, CA (US); Janos Veres, San Jose, CA (US)

(73) Assignee: PALO ALTO RESEARCH CENTER INCORPORATED, Palo Alto, CA (US)

(21) Appl. No.: 13/452,659

(22) Filed: Apr. 20, 2012

(51) Int. Cl. H01L 29/788; H01L 21/283

(52) U.S. Cl. 257/316; 438/593; 257/E29.3; 257/E21.19

(57) ABSTRACT

A floating gate transistor, comprising source and drain electrodes covered by a first dielectric separated by a channel, a floating gate electrode on the first dielectric arranged over the channel, an interlayer at least partially comprised of a semiconductor material and an organic material, and a control gate on the interlayer electrically coupled to the gate electrode.

### BACKGROUND

Non-volatile memory devices such as flash drives often use floating gate transistors as the memory elements. The memory hysteresis depends upon the amount of stored charge on the floating gate. Some of these devices use organic materials. Typically, the current devices rely on tunneling charge through nanometer thick dielectrics.

The thin layer of dielectric requires strict control over the dielectric thickness to enable the tunneling mechanism. The raises the expense of the process. Further, if the control fails, the device is inoperable, lowering the manufacturing yield.

Examples of these devices include, “Non-Volatile Memory Transistor with Nanotube Floating Gate,” assigned to Atmel Corporation, publication number of WO 2006/107398. In this example, the thin layer includes nanotubes. Another example includes “Nonvolatile nano-floating gate memory devices based on pentacene semiconductors and organic tunneling insulator,” Soo-Jin Kim, et al., Appl. Phys. Lett. 96, 033302 (2010). These approaches all show variations of the nanometer thin dielectric. Other examples using organic materials are “Organic Field-Effect Transistors with Polarizable Gate Insulators,” H. E. Katz, et al., J. Appl. Phys. 91, 1572 (2002); and “Degradation Mechanisms of Organic Ferroelectric Field-Effect Transistors Used as Nonvolatile Memory,” Ng, Russo, Arias, J. Appl. Phys. 106 (2009) 094504.

### BRIEF DESCRIPTION OF THE DRAWINGS

FIG. 1 shows a previous embodiment of a floating gate transistor.

FIG. 2 shows an embodiment of a floating gate transistor having an interlayer.

FIG. 3 shows a graph of transfer characteristics of an organic thin film transistor.

FIG. 4 shows a graph of transfer characteristics of a memory transistor using TPD-PS at an 80:20 blend.

FIG. 5 shows a graph of voltage switching windows for different blend compositions of floating gate dielectrics.

FIG. 6 shows a graph of minor hysteresis loops of a floating gate memory transistor.

FIG. 7 shows a graph of current change with time for a floating gate memory transistor.

FIGS. 8-9 shows graphs of transfer characteristics of a memory transistor with polystyrene floating gate transistor, and a hysteresis of the device with repeated voltage sweeps.

### DETAILED DESCRIPTION OF THE EMBODIMENTS

It has been discovered that the floating gate device structure can be made thicker by the introduction of an intrinsic semiconductor layer between the gate and the floating gate. This is advantageous for manufacturing purposes and is potentially advantageous for the characteristics of the device. Intrinsic semiconductors are insulating unless charge is injected into their volume. In the current invention, the charge carriers i.e. electrons or holes are injected into the intrinsic interlayer from the gate and transported to the floating gate where they remain essentially trapped. To ensure carrier injection is possible, an ohmic contact is engineered between the gate and the semiconductor interlayer. Once the carriers reach the floating gate, the transistor memory element turns on and whilst the floating gate is charged, the transistor remains in that state. To ensure that carriers stored in the floating gate do not easily return to the gate through the interlayer two approaches can be used.

First, the contact between the floating gate and the interlayer is engineered such that carrier injection back to the interlayer is energetically hindered. This can be achieved by appropriately choosing the floating gate material. For example, for a p-type, hole transporting interlayer, a low workfunction metal can be used in the floating gate. Alternatively, the floating gate may comprise another semiconductor that has a lower ionization potential. In other words the highest occupied molecular orbital, HOMO of the floating gate is a trap for holes in the interlayer. A second mechanism through which reverse flow of carriers is hindered from the floating gate is that when the gate bias is reversed, the channel of the memory transistor is depleted or partially depleted and therefore the field across the floating gate layer structure is reduced. Preferred interlayer materials of the current invention comprise organic semiconductors, which are easily processable by solution coating or printing techniques. Any organic semiconductor can be used as long as it is substantially intrinsic, meaning it is undoped and has conductivity of typically less than 10⁻¹⁰ S/m. Suitable materials are described in U.S. Pat. Nos. 7,718,734 and 7,576,208, without limitation and merely as examples.

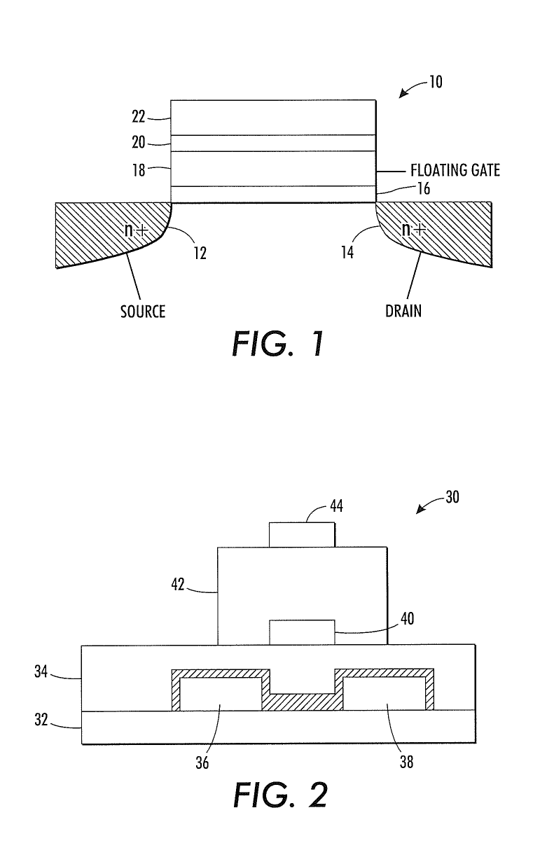

FIG. 1 shows an embodiment of a current architecture of a floating gate transistor. The transistor 10 has a source 12 and a drain 14. A layer of dielectric 16 separates the floating gate 18 from the source and drain layer. The floating gate 18 then has a very thin layer of dielectric 20, referred to as an interlayer. The interlayer generally has a very tightly controlled thickness. The control gate 22 then resides on the interlayer.

In the embodiments discussed below, the floating gate connects to the gate through an interlayer consisting of an intrinsic organic semiconductor. FIG. 2 shows an example of such a structure. Similar to the device of FIG. 1, the substrate 32 has a source 36 and a drain 38. These are covered with a dielectric 34, upon which resides the floating gate 40 over the channel between the source and drain. The floating gate is covered by an interlayer 42, upon which resides the control gate 44.

The interlayer may consist of an insulator blended with organic semiconductor molecules or a semiconducting polymer or oligomer. The organic semiconductor interlayer allows charge transport and charge accumulation to the floating gate. These architectures allow reliable memory devices without the need for very thin dielectric to enable tunneling. Charge accumulation at the floating gate results from a hopping process through the intrinsic organic semiconductor. Because of the intrinsic organic semiconductor, the interlayer can be much thicker. The organic semiconductor interlayer has higher reliability and compatibility with printing processes than previous devices with nanometer floating gate dielectrics.

Typically, the intrinsic semiconductor has an opposite transport property to that of the channel of the thin film transistor (TFT). For example, an n-channel transistor has an interlay of an intrinsic organic semiconductor layer capable of transporting holes, a p-channel semiconductor. Conversely, a p-channel transistor built with an interlayer of an intrinsic organic semiconductor layer capable of transporting electrons, an n-channel semiconductor.

The floating gate may consist of any metal or semiconductor material. The floating gate comprises a material that has a reverse barrier for injecting carriers into the organic semiconductor interlayer. The barrier prevents reverse injection of carriers into the interlayer and therefore aides charge retention. The barrier might be provided by choosing a metal with a workfunction higher than the characteristic transport level in an n-type organic semiconductor. For a p-type interlayer, the barrier might be provided by a metal with a workfunction lower than the characteristic transport level for the p-type interlayer semiconductor. The term workfunction as used here means energy to take away an electron from a conductor. For example, typical floating gate materials for p-type interlayers may be chosen from aluminum, silver, copper, calcium or similar materials. Examples of floating gate materials for n-type interlayers are gold, platinum, titanium, or a conducting polymer like PEDOT:PSS [Poly (3,4-ethylenedioxythiophene) poly(styrenesulfonate].

The floating gate may also comprise organic or inorganic semiconductors that act as traps relative to the transport level of the interlayer semiconductor. In this example, the traps provide a reverse injection barrier. The reverse injection barrier may also be provided by a thin insulating coating on the floating gate material. The insulating layer may be a thin layer of surface functionalization. The floating gate may be continuous or discontinuous. In one example, the floating gate is discontinuous to resemble small islands or nanoparticles, each capable of trapping charges with a reverse barrier for injection. The floating gate may comprise a nanoparticle silver composition.

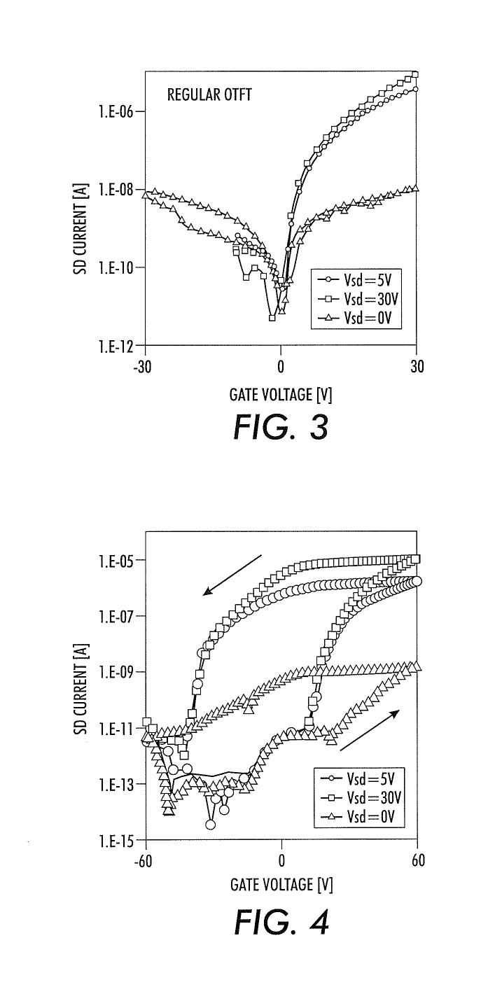

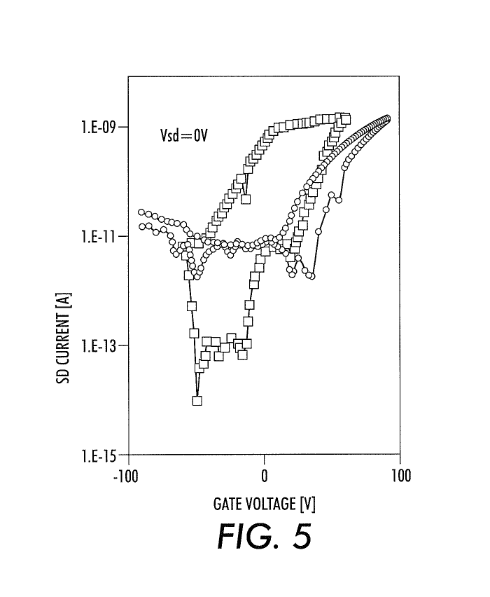

FIG. 3 shows transfer characteristics for an example organic TFT. Hysteresis is not observed in the transfer characteristics. In contrast, FIG. 4 shows the transfer characteristics of a device having an architecture such as that shown in FIG. 2. The data in the following figures shows characteristics of an n-type organic semiconductors of perylene derivatives in the channel, while the floating gate dielectrics consists of a polymer such as polystyrene (PS) blended with a p-type semiconductor, in this case triphenyldiamines (TPD), although other molecularly doped polymers and other organics may also be used. One should note that the reverse case also applies, that of a channel semiconductor of p-type and the floating gate dielectric blended with n-type semiconductor molecules.

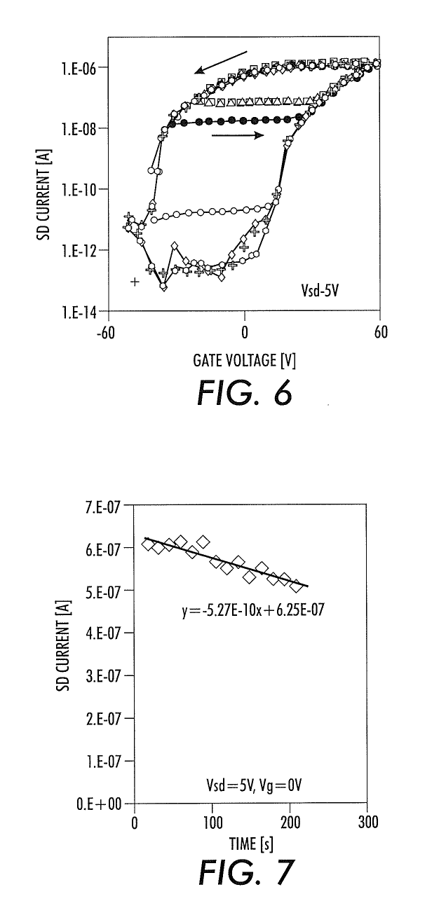

The embodiment of the device having the data shown in FIG. 4 consisted of an 80% TPD:20% PS solution spincoated to form a 1 micron thick film. The memory transistor switches on at 30V and to the off state at −50V. The switching voltage can vary according to the floating gate dielectric thickness, as well as by the composition of the semiconductor-instructor blend. FIG. 6 shows an example of switching voltages for two different blends of TPD-PS.

FIG. 6 shows results of measuring minor hysteresis loops for an example transistor such as those discussed above. FIG. 7 shows data related to the time for the device current to drop to half of its original value, extrapolated to be 10 minutes. The retention time is relatively short but comparable to previous organic floating gate memories that are applicable as dynamic random access memories. The switching frequency is estimated to be 4000 Hz, approximately 250 microseconds for a 1 micron thick TPD-PS (80%:20%) blend, with transport mobility approximately equal to 1e-6 cm²/Vs.

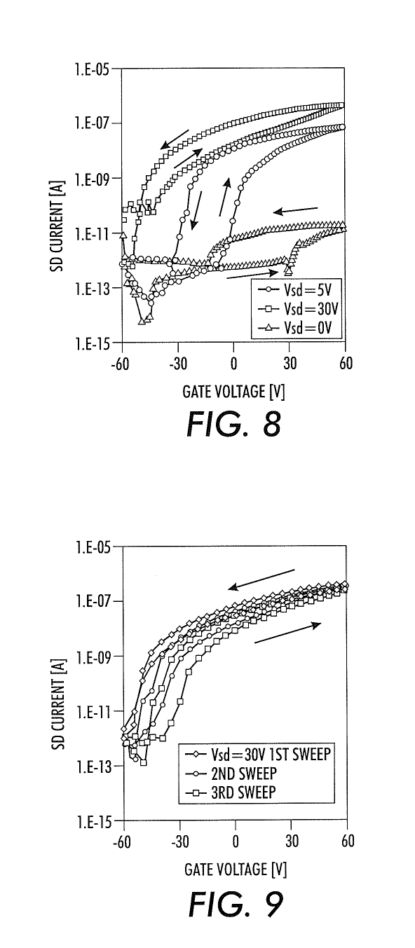

The addition of semiconductor molecules to the floating gate dielectrics is essential for stable hysteresis, if the dielectric has a thickness beyond the nanometer range. FIGS. 8-9 show a device where the floating gate dielectrics consists of 400 nm polystyrene with no semiconductor added. The measured hysteresis is not stable. The charge transport is slow without the added semiconductor, and the device characteristics continually drift with additional input charge.

The addition of semiconducting molecules to the floating gate dielectrics enables better charge transport to the floating gate. This can improve yield of floating gate transistors, because thick dielectric can be used and issues with electrical shorts can be mitigated. The semiconductor/insulator blend is completely soluble in organic solvent. Generally, the blend will form smoother films than previous blends using nano-particles, such as carbon nanotubes, oxide, metal particles or the like.

Other modifications or variations are of course possible. As discussed above, the semiconductor in the blend can be p-type or n-type, depending upon the polarity needed to accumulate charge in transistor channel. The floating gate dielectric may be patterned or blanket deposited. The thickness of the dielectric and composition of the semiconductor/insulator blend ratio can be tuned to obtain the desired voltage range of the memory window. Different floating gate materials can be used in relation to the work function of the semiconductor/insulator blend, or order to prolong charge retention time.

Charge transport to a floating gate is improved by using an injection layer comprising an intrinsic organic semiconductor. With such a layer, devices can be built with a thick layer above the floating gate, making fabrication easier. The use of organic semiconductor as floating gate dielectric provides a more homogeneous film than previous nanoparticle blends. Such layers offer also higher degree of charge displacement to the extent of the full thickness of the floating gate injection layer. The voltage range of memory window can be adjusted by the thickness of the injection layer or by varying the mobility of the injection layer, such as by the choice of materials or blends. The floating gate material is chosen such as to stop reverse injection below a certain bias. The reverse bias required can be readily adjusted by the workfunction of the metal or semiconductor materials employed in the injection layer and the floating gate itself. Floating gate memory cells can be arranged in array form, as shown in the reference, “Organic Inkjet Patterned Memory Array Based on Ferroelectric Field-Effect Transistors,” Ng, Russo, Arias, Org. Electron., 12 (2011) 2012-2018, and in U.S. Pat. No. 8,158,973, “Organic Memory Array with Ferroelectric Field-Effect Transistor Pixels.”

It will be appreciated that several of the above-disclosed and other features and functions, or alternatives thereof, may be desirably combined into many other different systems or applications. Also that various presently unforeseen or unanticipated alternatives, modifications, variations, or improvements therein may be subsequently made by those skilled in the art which are also intended to be encompassed by the following claims.

1. A floating gate transistor, comprising:
source and drain electrodes, separated by a channel, the source and drain electrodes covered by a first dielectric;
a floating gate electrode on the first dielectric arranged over the channel;
an interlayer at least partially comprised of a semiconductor material and an organic material covering the floating gate electrode; and
a control gate on the interlayer electrically coupled to the gate electrode.

2. The floating gate transistor of claim 1, wherein the interlayer has an opposite transport property to the channel.

3. The floating gate transistor of claim 1, wherein the floating gate comprises a semiconductor or metal material.

4. The floating gate transistor of claim 1, wherein the floating gate comprises a material that has a reverse barrier, the reverse barrier arranged to inject carriers into the interlayer.

5. The floating gate transistor of claim 4, wherein the reverse barrier comprises one of an organic semiconductor, an inorganic semiconductor, or an insulating coating on the floating gate.

6. The floating gate transistor of claim 1, wherein the floating gate is continuous.

7. The floating gate transistor of claim 1, wherein the floating gate is discontinuous.

8. The floating gate transistor of claim 7, wherein the floating gate comprises a nanoparticle silver composition.

9. The floating gate transistor of claim 1, wherein the interlayer comprises a polymer blended with a semiconductor.

10. The floating gate transistor of claim 9, wherein the interlayer semiconductor is a p-type semiconductor and the channel is an n-type semiconductor.

11. The floating gate transistor of claim 10, wherein the p-type semiconductor comprises one of triphenyldiamines, molecularly doped polymers, or molecularly doped organics.

12. The floating gate transistor of claim 9, wherein the interlayer semiconductor is an n-type semiconductor and the channel is a p-type semiconductor.

13. The floating gate transistor of claim 1, wherein the interlayer comprises a triphenyldiamines polystyrene blend.

14. The floating gate transistor of claim 1, wherein the interlayer has a thickness in a range of 500 nanometers to 2 micrometers.

15. A method of manufacturing a floating gate transistor, comprising:
forming source and drain electrodes on a substrate, the source and drain electrodes arranged to have a channel between them;
covering the source and drain electrodes and the channel with a first dielectric;
forming a floating gate electrode on the first dielectric arranged over the channel;
depositing an interlayer material on the floating gate electrode to cover the floating gate electrode, the interlayer material comprising an organic material mixed with a semiconductor material; and
forming a control gate on the interlayer material.

16. The method of claim 15, the method further comprising depositing an insulating coating on the floating gate electrode.

17. The method of claim 15, wherein depositing the interlayer material comprises one of depositing the interlayer having a p-type semiconductor over an n-type channel or depositing the interlayer having an n-type semiconductor over a p-type channel.

18. The method of claim 15, wherein forming the floating gate electrode comprises forming a floating gate from one of aluminum, silver, copper, calcium, gold, platinum, titanium, or PEDOT:PSS.

19. The method of claim 15, wherein depositing the interlayer material comprises depositing one of a blend of polystyrene and triphenyldiamines, a molecularly doped polymer, or a molecularly doped organic.

20. The method of claim 15, wherein depositing the interlayer material comprises depositing the interlayer material to a thickness in a range of 500 nanometers to 2 micrometers.
